(19) United States
(12) Patent Application Publication
(10) Pub. No.: US 2024/0387563 A1
(43) Pub. Date: Nov. 21, 2024

(54) DISPLAY PANEL

(71) Applicant: WUHAN CHINA STAR OPTOELECTRONICS TECHNOLOGY CO., LTD., Wuhan, Hubei (CN)

(72) Inventor: Hailong PAN, Wuhan, Hubei (CN)

(21) Appl. No.: 17/597,235

(22) PCT Filed: Dec. 24, 2021
(86) PCT No.: PCT/CN2021/141273

§ 371 Date: Aug. 5, 2024

(30) Foreign Application Priority Data
Dec. 20, 2021 (CN) 202111564444.4

(51) Int. Cl. H01L 27/12; G02F 1/1362

(52) U.S. Cl. CPC H01L 27/1244; G02F 1/136222; G02F 1/136286

(57) ABSTRACT

A display panel (100), comprising a driving chip (201) and bonding pad groups (202), which are electrically connected to each other, and an array substrate (10) and a color filter (30), which are arranged opposite each other, wherein the array substrate (10) comprises a first area (A1) and a second area (A2), which are arranged in a first direction (D1); the driving chip (201) is located in a third area (A3), which corresponds to an opening (301) in the color filter (30) on the side of the array substrate (10) that is close to the color filter (30); and the orthographic projection of the driving chip (201) overlaps the orthographic projection of the bonding pad group (202) on a first plane parallel to the first direction (D1) and perpendicular to the display panel (100).

### FIELD OF INVENTION

The present application relates to a technical field of displays, and particularly to a manufacturing of a display panel and a display panel.

### RELATED ART

Currently, market's demands for narrow bezels of display screens are getting higher and higher, so that full screen displays have become popular.

Specifically, in current chip on glass (COG) panels, driver chips are located below display areas. Since sides of the driver chips away from the display areas need to be provided with bonding pads arranged sequentially, flexible printed circuits need to be bonded to the bonding pads, and bending areas need to be reserved for bending of the flexible printed circuit boards, the size of lower portions of the display areas are forced to be larger, which greatly increases the size of lower frames of the display panels and is not conducive to the development of the narrow bezel of the displays.

Accordingly, it is imperative to improve the situation that the arrangement of driver chips, bonding pads, and flexible printed circuit boards of panels in prior art is not conducive to the development of the narrow bezel of the displays.

### SUMMARY OF INVENTION

### Technical Problem

The embodiment of the present invention provides a display panel to solve the technical problem that arrangement of driver chips, bonding pads, and flexible printed circuit boards in current panels is not conducive to the development of the narrow bezel of a display.

### Solutions to Technical Problems

### Technical Solution

In order to overcome the above-mentioned problem, an embodiment of the present invention provides a display panel, comprising:

an array substrate comprises a first area and a second area arranged in a first direction;

a driving assembly comprising a driver chip located in the second area and at least a bonding pad group electrically connected to the driver chip, and the driving assembly electrically connected to driving wirings located in the first area; and

a color filter substrate disposed opposite to the array substrate. An opening is located at the color filter substrate, and the driver chip is located in a third area opposite to the opening on a side of the array substrate close to the color filter substrate;

wherein an orthographic projection of the driver chip on a first plane overlaps an orthographic projection of the bonding pad group on the first plane, and the first plane is parallel to the first direction and perpendicular to the display panel;

the bonding pad group is disposed on both sides of the driver chip, the orthographic projection of the driver chip on the first plane is within the orthographic projection of the bonding pad group on the first plane, or the orthographic projection of the bonding pad group on the first plane is within the orthographic projection of the driver chip on the first plane.

In one embodiment, the bonding pad group is located on the side of the array substrate close to the color filter substrate;

wherein the driving assembly further comprises a flexible printed circuit board connected to a side of the display panel close to the bonding pad group and bent such that the flexible printed circuit board is fixed to a side of the array substrate away from the color filter substrate, and the flexible printed circuit board is electrically connected to the bonding pad group.

In one embodiment, the bonding pad group is electrically connected to the driver chip through a wire group, and the driver chip is electrically connected to the driving wirings.

In one embodiment, the orthographic projection of the driver chip on the first plane is within the orthographic projection of the bonding pad group on the first plane;

wherein the bonding pad group comprises a plurality of bonding pads, and each of the bonding pads comprises a first end and a second end that are arranged opposite to each other in the first direction, wherein a plurality of the first ends in the bonding pad group are arranged in alignment with each other in a second direction, and the second direction is perpendicular to the first direction, wherein a size of one of adjacent ones of the bonding pads close to the driver chip in the first direction is less than a size of the other one of the adjacent bonding pads away from the driver chip in the first direction, so that the second ends in the bonding pad group each have a size difference in the first direction; and wherein the wire group comprises a plurality of wires arranged in a one-to-one correspondence with the bonding pads, the second end of each of the bonding pads is electrically connected to the driver chip through a corresponding one of the wires, and each of the wires is located in a size difference area defined by the corresponding bonding pad.

In one embodiment, the display panel further comprises:

a sealant located between the color filter substrate and the array substrate and disposed at least opposite to a periphery of the opening.

In one embodiment, the display panel further comprises:

a plurality of supporting parts located between the color filter substrate and the array substrate, and the supporting parts are arranged at least along a periphery of the opening.

In one embodiment, at least one of the bonding pad groups comprises a plurality of the bonding pads arranged in the second direction or in the first direction, the second direction is perpendicular to the first direction.

The present invention further provides a display panel, comprising:
an array substrate comprises a first area and a second area arranged in a first direction;
a driving assembly comprising a driver chip located in the second area and at least a bonding pad group electrically connected to the driver chip, and the driving assembly electrically connected to driving wirings located in the first area;
a color filter substrate disposed opposite to the array substrate. An opening is located at the color filter substrate, and the driver chip is located in a third area opposite to the opening on a side of the array substrate close to the color filter substrate;
wherein an orthographic projection of the driver chip on a first plane overlaps an orthographic projection of the bonding pad group on the first plane, and the first plane is parallel to the first direction and perpendicular to the display panel.

In one embodiment, the bonding pad group is located on the side of the array substrate close to the color filter substrate;
wherein the driving assembly further comprises a flexible printed circuit board connected to a side of the display panel close to the bonding pad group and bent such that the flexible printed circuit board is fixed to a side of the array substrate away from the color filter substrate, and the flexible printed circuit board is electrically connected to the bonding pad group.

In one embodiment, the bonding pad group is electrically connected to the driver chip through a wire group, and the driver chip is electrically connected to the driving wirings.

In one embodiment, the bonding pad group is disposed on both sides of the driver chip.

In one embodiment, the orthographic projection of the driver chip on the first plane is within the orthographic projection of the bonding pad group on the first plane, or the orthographic projection of the bonding pad group on the first plane is within the orthographic projection of the driver chip on the first plane.

In one embodiment, the orthographic projection of the driver chip on the first plane is within the orthographic projection of the bonding pad group on the first plane;
wherein the bonding pad group comprises a plurality of bonding pads, and each of the bonding pads comprises a first end and a second end that are arranged opposite to each other in the first direction, wherein a plurality of the first ends in the bonding pad group are arranged in alignment with each other in a second direction, and the second direction is perpendicular to the first direction, a size of one of adjacent ones of the bonding pads close to the driver chip in the first direction is less than a size of the other one of the adjacent bonding pads away from the driver chip in the first direction, so that the second ends in the bonding pad group each have a size difference in the first direction;
wherein the wire group comprises a plurality of wires arranged in a one-to-one correspondence with the bonding pads, the second end of each of the bonding pads is electrically connected to the driver chip through a corresponding one of the wires, and each of the wires is located in a size difference area defined by the corresponding bonding pad.

In one embodiment, the display panel further comprises:
a sealant located between the color filter substrate and the array substrate and disposed at least opposite to a periphery of the opening.

In one embodiment, the display panel further comprises:
a plurality of supporting parts located between the color filter substrate and the array substrate, and the supporting parts are arranged at least along a periphery of the opening.

In one embodiment, the driver chip is located on the side of the array substrate that is away from the color film substrate;
wherein, the driver chip is fixed on the side of the flexible printed circuit board that is away from the color film substrate, the driving chip is electrically connected to the flexible printed circuit board, and the bonding pad groups are electrically connected to the driving wirings.

In one embodiment, at least one of the bonding pad groups comprises a plurality of the bonding pads arranged in the second direction or in the first direction, the second direction is perpendicular to the first direction.

In one embodiment, each of the bonding pad groups comprises a plurality of the bonding pads arranged in the first direction, and each of the bonding pads comprises a contact end disposed close to an edge of the display panel;
wherein the flexible printed circuit board is arranged close to and connected to the plurality contact ends in the bonding pad group.

In one embodiment, the first area comprises a fourth area adjoining a periphery of the array substrate in the first direction;
wherein the driving wirings located in the fourth area are arranged in layers, and the driving wirings located in different layers are electrically connected through via holes.

In one embodiment, the driving assembly further comprises a conductive portion located between a side of the display panel and the flexible printed circuit board;
wherein one side of the conductive portion is electrically connected to the bonding pad group, and the other side is electrically connected to the flexible printed circuit board.

In one embodiment, the display panel further comprises:
a fixing part located on an edge of the display panel close to the flexible printed circuit board and connected to the edge of the display panel and the flexible printed circuit board.

### Beneficial Effects of the Present Disclosure

### Beneficial Effects

The present application has advantageous effects as follows: the present invention provides the display panel including: the array substrate including the first area and the second area arranged in the first direction, and the first area is configured for display. The driving assembly includes the driver chip located in the second area and at least one bonding pad group electrically connected to the driver chip. The driving assembly is electrically connected to the driving wirings located in the first area. The color filter substrate and the array substrate are arranged oppositely, and the color filter substrate is formed with the opening. The driver chip is located in the third area opposite to the opening on the side of the array substrate close to the color filter substrate. Specifically, an orthographic projection of the driver chip on a first plane overlaps an orthographic projection of the bonding pad group on the first plane, and the first plane is parallel to the first direction and perpendicular to the display panel. In the present invention, the driver chip is disposed such that the driver chip after extending in the second direction can overlap the bonding pad group, making the projection of the driver chip in the second direction overlap the projection of the bonding pad group in the second direction. The second direction is perpendicular to the first direction. In this fashion, the projections of the bonding pad group and the driver chip can be prevented from separately occupying extra space in the first direction. In addition, a relatively large size of a sum of the projections in the first direction can be prevented, which effectively shortens the size of the array substrate in the first direction, and is beneficial to the development of the narrow bezel of the display panel.

### BRIEF DESCRIPTION OF DRAWINGS

### Description of Drawings

In order to more clearly illustrate the technical solutions in the embodiments of the present invention, the following briefly introduces the accompanying drawings for describing the embodiments. Apparently, the accompanying drawings in the following description show merely some embodiments of the present invention, and a person skilled in the art may still derive other drawings from these accompanying drawings without creative efforts.

In order to more clearly illustrate the technical solutions in the embodiments of the present invention, the following briefly introduces the accompanying drawings for describing the embodiments. Apparently, the accompanying drawings in the following description show merely some embodiments of the present invention, and a person skilled in the art may still derive other drawings from these accompanying drawings without creative efforts.

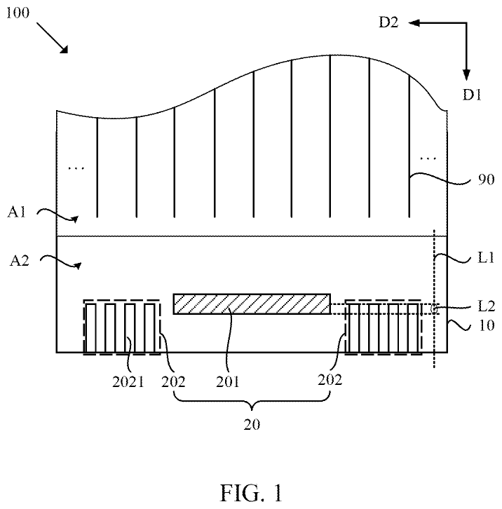

FIG. 1 is a schematic top plan view of an array substrate of a first type of a display panel provided by the present application.

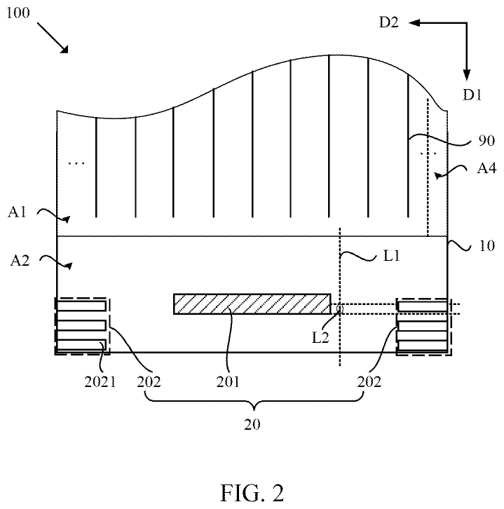

FIG. 2 is a schematic top plan view of an array substrate of a second type of a display panel provided by the present application (including a perspective structure of a driver chip).

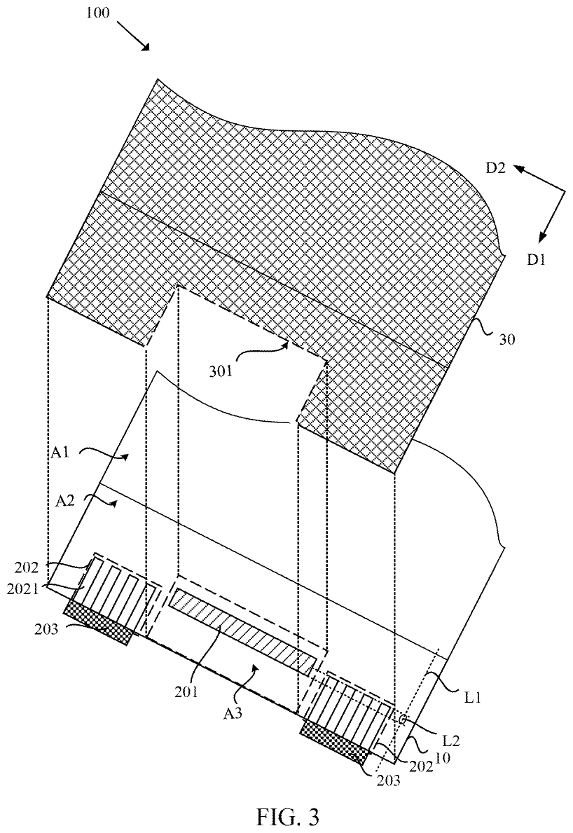

FIG. 3 is a schematic exploded structural view of the first type of the display panel provided by the present application.

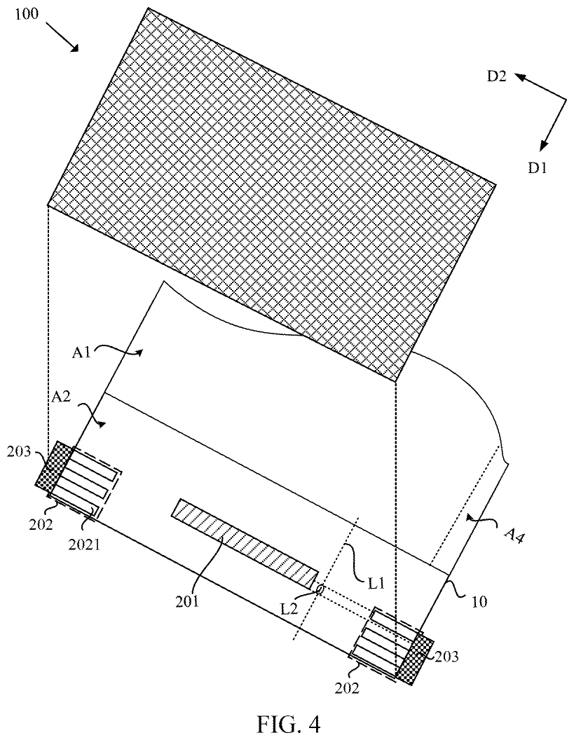

FIG. 4 is a schematic exploded structural view of the second type of the display panel provided by the present application (including the perspective structure of the driver chip).

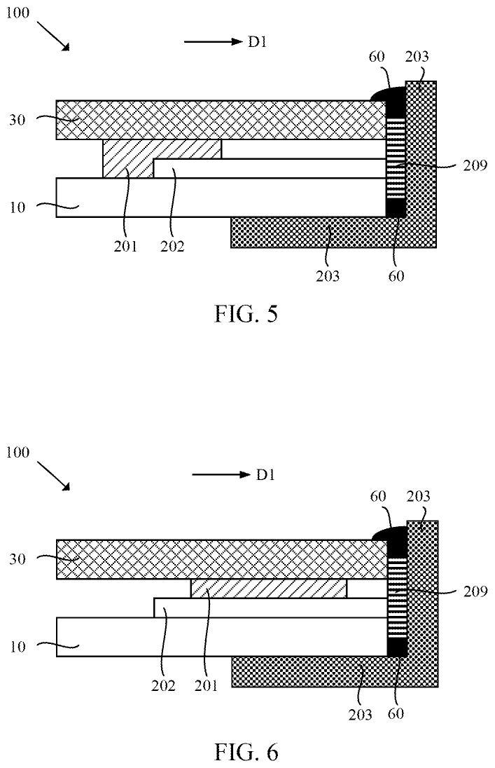

FIG. 5 is a left side view showing part of the first type of the display panel provided by the present application.

FIG. 6 is a front view showing part of the second type of the display panel provided by the present application.

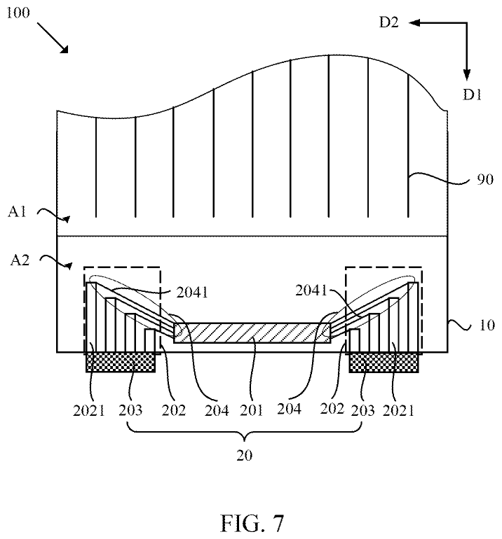

FIG. 7 is a schematic top plan view of an array substrate of a third type of a display panel provided by the present application.

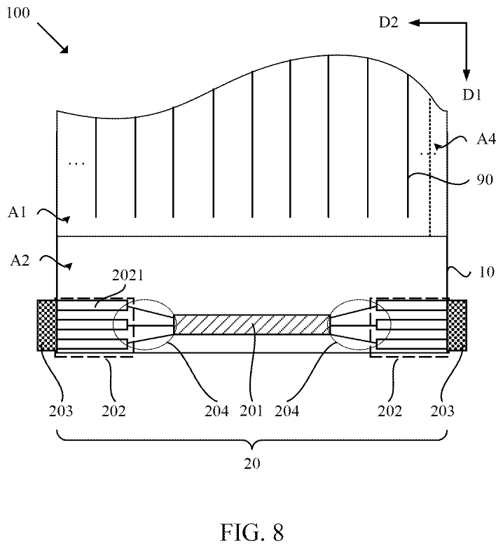

FIG. 8 is a schematic top plan view of an array substrate of a fourth type of a display panel provided by the present application.

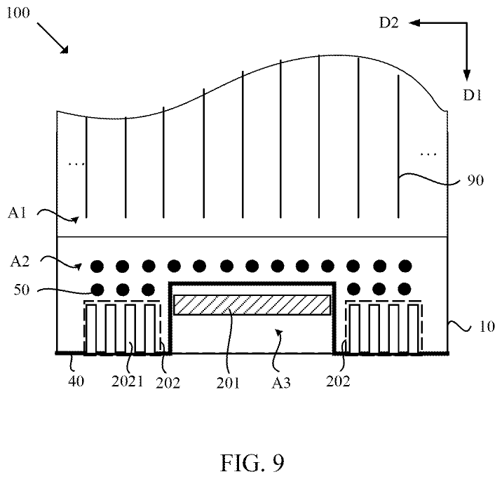

FIG. 9 is a schematic top plan view of the array substrate and a structure provided on the array substrate of the first type of the display panel provided by the present application.

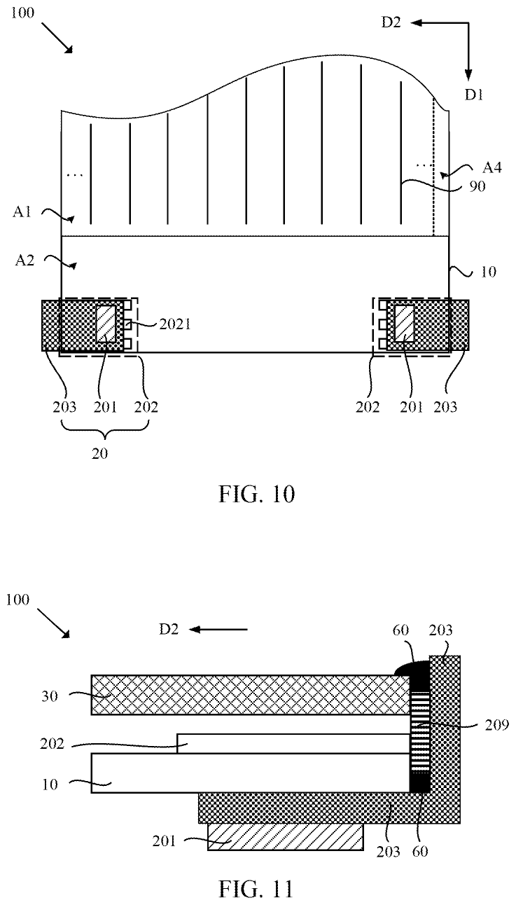

FIG. 10 is a schematic bottom plan view of the array substrate and a structure provided below the array substrate of the second type of the display panel provided by the present application.

FIG. 11 is a front view showing part of the second type of the display panel provided by the present application.

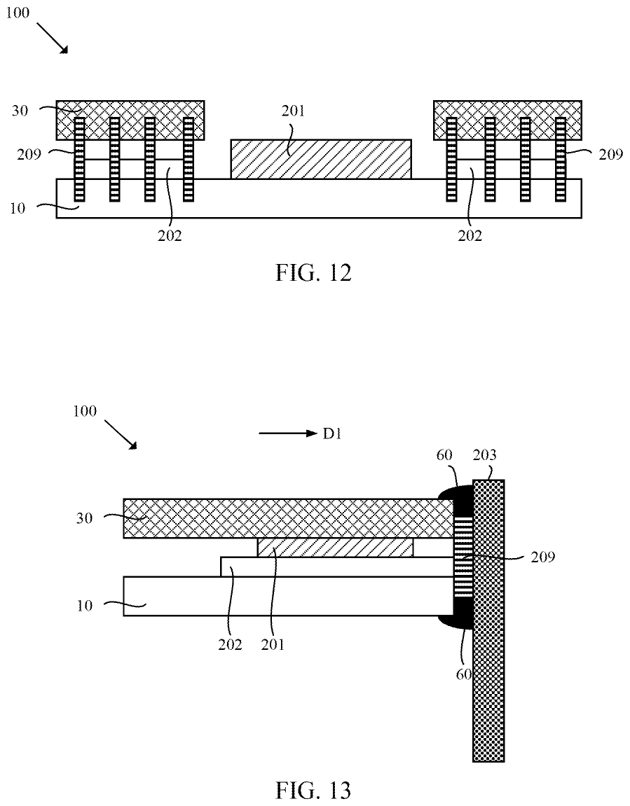

FIG. 12 is a front view showing part of the first type of the display panel provided by the present application.

FIG. 13 is a left side view of a flexible printed circuit board without bending in the second type of the display panel provided by the present application.

### DESCRIPTION OF EMBODIMENTS

### Embodiments of the Present Invention

The technical solutions in the embodiments of the present invention will be clearly and completely described below in conjunction with the drawings in the embodiments of the present invention. Obviously, the described embodiments are only a part of the embodiments of the present invention, rather than all the embodiments. Based on the embodiments in this invention, all other embodiments obtained by those skilled in the art without creative work shall fall within the protection scope of this invention.

The terms “first”, “second”, “third”, etc. in the present invention are used to distinguish different objects, rather than to describe a specific sequence. In addition, the terms “including” and “having” and any variations thereof are intended to cover non-exclusive inclusions. For example, a process, method, system, product, or device that includes a series of steps or modules is not limited to the listed steps or modules, but optionally includes steps or modules that are not listed, or optionally also includes other steps or modules inherent to these processes, methods, products or equipment.

Reference to “embodiments” herein means that a specific feature, structure, or characteristic described in conjunction with the embodiments may be included in at least one embodiment of the present invention. The appearance of the phrase at various time positions in the specification does not necessarily refer to the same embodiment, nor is it an independent or alternative embodiment mutually exclusive with other embodiments. Those skilled in the art clearly and implicitly understand that the embodiments described herein can be combined with other embodiments.

The disclosure will be further described below in conjunction with the drawings and specific embodiments: The embodiment of the present invention provides a display panel, and the display panel includes but is not limited to the following embodiments and combinations between the following embodiments.

In one embodiment, as shown in FIGS. 1 and 2, the display panel 100 includes an array substrate 10 including a first area A1 and a second area A2 arranged in a first direction D1, and the first area A1 is configured for displaying. The driving assembly 20 includes a driver chip 201 located in the second area A2 and at least one bonding pad group 202 electrically connected to the driver chip 201, and the driving assembly 20 is electrically connected to driving wirings 90 located in the first area A1. Specifically, an orthographic projection of the driver chip 201 on a first plane overlaps an orthographic projection of the bonding pad group 202 on the first plane, and the first plane is parallel to the first direction D1 and perpendicular to the display panel 100. As shown in FIG. 1, it can also be understood that the projection of the driver chip 201 in the second direction D2 overlaps the projection of the bonding pad group in the second direction D2, and the second direction D2 is perpendicular to the first direction D1.

Specifically, two ends of the driver chip 201 are electrically connected to the driving wirings 90 and the at least one bonding pad group 202 located in the first area A1, respectively. Here, a first auxiliary line L1 is defined as an auxiliary line located on the array substrate 10 and parallel to the first direction D1. If the bonding pad group 202 is arranged on a side of the driver chip 201 away from the first area A1, that is, each of the projection of the bonding pad group 202 on the first auxiliary line L1 and the projection of the driver chip 201 on the first auxiliary line L1 takes up space without overlap with each other. As a result, a size of the second area A2 in the first direction D1 is relatively large, which is not conducive to the development of a narrow bezel of the display panel.

It can be understood that in this embodiment, the driver chip 201 is configured such that the projection of the driver chip 201 in the second direction D2 overlaps the projection of the bonding pad group in the second direction D2, that is, the driver chip 201 extends in the second direction D2 and then overlaps the bonding pad group 202. That is, the projection of the bonding pad group 202 on the first auxiliary line L1 and the projection of the driver chip 201 on the first auxiliary line L1 overlap with each other, so as to prevent the bonding pad group 202 and the driver chip 201 from occupying extra space due to the absence of an overlapping area of their projections. In other words, a second auxiliary line L2 is defined to cover a total area of the projection of the bonding pad group 202 and the projection of the driving chip 201 on the first auxiliary line L1, and a required length of the second auxiliary line L2 may be less than a size of the bonding pad group 202 in the first direction D1 and a size of the driver chip 201 in the first direction D1. According to the above-mentioned analysis, a size of the second area A2 in the first direction D1 is correspondingly reduced, which is beneficial to the development of the narrow bezel of the display panel.

It should be noted that the first auxiliary line L1 and the second auxiliary line L2 do not exist on the array substrate 10 here, but are only auxiliary lines assumed for the convenience of analysis. Specifically, the display panel includes a front side and a back side oppositely arranged, and the first area A1 defined for display is located on the front side of the array substrate 10 here. The arrangement of the first area A1 and the second area A2 is limited only in the first direction D1 in this embodiment. The second area A2 here may be located on the front side and the back side of the array substrate 10, or a portion on the front side and the back side of the array substrate 10 adjacent to the first area A1 in the first direction D1 may be included in the second area A2. That is, in this embodiment, there is no restriction on the driver chip 201 being located on the front side or the back side of the array substrate 10, and there is no restriction on whether the bonding pad group 202 is located on the front side or the back side of the array substrate 10. For example, as shown in FIG. 1, the driver chip 201 and the bonding pad group 202 may be located on the front side of the array substrate 10; as another example, the bonding pad group 202 shown in FIG. 2 may be located on the front side of the array substrate 10 and the driver chip 201 may be located on the back side of the array substrate 10.

In an embodiment, as shown in FIGS. 3 and 4, the display panel 100 further includes a color filter substrate 30, and the color filter substrate 30 and the array substrate 10 are arranged opposite to each other. The bonding pad group 202 is located on a side of the array substrate 10 close to the color filter substrate 30. As shown in FIG. 3, the driver chip 201 is located on the side of the array substrate 10 close to the color filter substrate 30, or as shown in FIG. 4, the driver chip 201 is located on a side of the array substrate 10 away from the color filter substrate 30. Specifically, the driving assembly 20 further includes a flexible printed circuit board 203 connected to the side of the display panel 100 close to the bonding pad group 202. As shown in FIGS. 3, 4, 5, and 6, the flexible printed circuit board 203 is further bent to be fixed to the side of the array substrate 10 away from the color filter substrate 30, and the flexible printed circuit board 203 is electrically connected to the bonding pad group 202.

A liquid crystal layer may be provided between the color filter substrate 30 and the array substrate 10, a backlight module may be provided on the side of the array substrate 10 away from the color filter substrate 30, an upper polarizer may be provided on the side of the color filter substrate 30 away from the array substrate 10, and a lower polarizer may be provided between the backlight module and the array substrate 10. Specifically, the backlight module provides light to the side close to the array substrate 10, and the lower polarizer is configured to convert the light beam generated by the backlight module into polarized light. The upper polarizer is configured to analyze the polarized light of a specific color that is electrically modulated by the liquid crystal layer and selected by the color film substrate 30 to generate a contrast between light and dark, thereby generating a display image.

Further, the bonding pad group 202 may be arranged close to at least one side of the array substrate 10. According to the above discussion, the flexible printed circuit board 203 is connected to the side of the display panel 100 close to the bonding pad group 202. It can be understood that the flexible printed circuit board 203 and the bonding pad group 202 are electrically connected to a side of the display panel 100. Further, the flexible printed circuit board 203 is further bent from a side of the display panel 100 to be fixed to the side the array substrate 10 away from the color filter substrate 30, thereby preventing that the flexible printed circuit board 203 is bent from the front side of the array substrate 10 and occupies too much space in the plane where the array substrate 10 is located, which is further conducive to the development of the narrow bezel of the display panel.

It should be noted that in this embodiment, the distribution of the bonding pad group 202 and the driver chip 201 in the first direction D1 is not limited, as long as the projections of the bonding pad group 202 and the driver chip 201 on the first auxiliary line L1 overlap. For example, as shown in FIG. 5, in the first direction D1, the bonding pad group 202 may exceed the driver chip 201. In a direction opposite to the first direction D1, the driver chip 201 may extend beyond the bonding pad group 202; alternatively, for example, as shown in FIG. 6, in the first direction D1 or in the direction opposite to the first direction D1, the bonding pad group 202 can exceed the driver chip 201.

In one embodiment, as shown in FIGS. 1 and 3, the driver chip 201 is located on the side of the array substrate 10 close to the color filter substrate 30; Specifically, as shown in FIGS. 1, 3, and 5-8, the bonding pad group 202 is electrically connected to the driver chip 201 through a wire group 204, and the driver chip 201 is electrically connected to the driving wirings 90.

Accordingly, the flexible printed circuit board 203 is electrically connected to the bonding pad group 202, and the bonding pad group 202 is electrically connected to the driver chip 201 through the wire group 204. The driver chip 201 is electrically connected to the driving wirings 90, that is, the flexible printed circuit board 203 can be electrically connected to the driving wirings 90 located in the first area A1 through the bonding pad group 202, the wire group 204, and the driver chip 201 in sequence, thereby controlling the display panel 100 for displaying. Specifically, a number of flexible printed circuit boards 203 can be two. For example, as shown in FIG. 1 and FIG. 3, the number of driver chips 201 may be one. The driver chip 201 may be disposed close to a middle of the second area A2 so as to be electrically connected to the bonding pad group 202 on at least one side through the wire group 204.

It can be understood that the flexible printed circuit board 203 and the driver chip 201 in this embodiment can be considered to be packaged by a chip on glass (COG) technology. That is, the driver chip 201 is located on the side of the array substrate 10 close to the color filter substrate 30, and the flexible printed circuit board 203 is bent from the side of the array substrate 10 close to the bonding pad group 202 to be fixed to the side of the array substrate 10 away from the color filter substrate 30. Specifically, the driver chip 201 is electrically connected to the flexible printed circuit board 203 through the wire group 204 and the bonding pad group 202 in order to be loaded with the original electrical signal. Further, a driving signal generated by processing an original signal through the driver chip 201 is transmitted to a light-emitting device through the driving wiring 90, so as to control image displaying of the display panel 100.

In one embodiment, as shown in FIGS. 7 and 8, the bonding pad group 202 is provided on both sides of the driver chip 201. It can be understood that the number of bonding pad groups 202 in this embodiment is set to be larger, which increases the number of original signals that the driver chip 201 can receive, thereby improving display quality of the display panel 100. Alternatively, it can be understood that the bonding pad group 202 has a large distribution area around the driver chip 201, which facilitates the electrical connection between the bonding pad group 202 and the driver chip 201, as well as shortening a length of the wire group 204 and improving the reliability of signal transmission.

As described above, the driver chip 201 after extending in the second direction D2 can overlap at least one bonding pad group 202 in this embodiment. Further, after the driver chip 201 in this embodiment extends in the second direction D2, the driver chip 201 may also overlap the two bonding pad groups 202, so that projections of the two bonding pad groups 202 on the first auxiliary line and the projection of the driver chip 201 on the first auxiliary line overlap. Still further, one of the bonding pad groups 202 after extending in the second direction D2 may also overlap the other bonding pad group 202, so that under the premise that the number and the distribution area of the bonding pad groups 202 increase, an increase in the size of the second area A2 in the first direction D1 can be prevented, which is beneficial to the development of the narrow bezel of the display panel.

In one embodiment, as shown in FIGS. 7 and 8, an orthographic projection of the driver chip 201 on the first plane is within an orthographic projection of the bonding pad group 202 on the first plane, or the orthographic projection of the bonding pad group 202 on the first plane is within the orthographic projection of the driver chip 201 on the first plane. Likewise, referring to FIG. 7 in combination with FIG. 8, it can also be understood that the orthographic projection of the driver chip 201 in the second direction D2 is within the orthographic projection of the bonding pad group 202 in the second direction D2, or the orthographic projection of the bonding pad group 202 in the second direction D2 is within the orthographic projection of the driver chip 201 in the second direction D2.

It can be understood that in this embodiment, regardless of the size of the driver chip 201 in the first direction D1 and the size of the bonding pad group 202 in the first direction D1, based on the limitations described above, a total length of the projection of the bonding pad group 202 on the first auxiliary line and the projection of the driver chip 201 on the first auxiliary line can be equal to the size of the driver chip 201 or the size of the bonding pad group 202 in the first direction D1, whichever is larger, thereby preventing the size of the smaller one having a projection in the second direction D2 beyond a projection of the size of the larger one, in order to take up additional space in the first direction D1, which is beneficial to the development of the narrow bezel of the display panel.

In one embodiment, as shown in FIG. 7, the orthographic projection of the driver chip 201 on the first plane is within the orthographic projection of the bonding pad group 202 on the first plane; similarly, further referring to FIG. 7, it can also be understood that the orthographic projection of the driver chip 201 in the second direction D2 is within the orthographic projection of the bonding pad group 202 in the second direction D2. Specifically, the bonding pad group 202 includes a plurality of bonding pads 2021. Each of the bonding pads 2021 includes a first end and a second end that are arranged opposite to each other in the first direction D1. A plurality of the first ends in the bonding pad group 202 are arranged in alignment with each other in the second direction D2. A size of one of adjacent ones of the bonding pads 2021 close to the driver chip 201 in the first direction D1 is less than a size of the other one of the adjacent bonding pads 2021 away from the driver chip 201 in the first direction D1, so that the second ends in the bonding pad group 202 each have a size difference in the first direction D1; specifically, the wire group 204 includes a plurality of wires 2041 arranged in a one-to-one correspondence with the bonding pads 2021, the second end of each of the bonding pads 2021 is electrically connected to the driver chip 201 through a corresponding one of the wires 2041, and each of the wires 2041 is located in a size difference area defined by the corresponding bonding pad 2021.

Specifically, in this embodiment, on the basis that the projection of the driver chip 201 in the second direction D2 is located within the bonding pad group 202, that is, in the first direction D1, the driver chip 201 is included in the bonding pad group 202, and a plurality of the first ends are further arranged in alignment with each other in the second direction D2. In addition, in the bonding pad group 202, the closer a distance to the driver chip 201 is, the smaller the size of the bonding pad 2021 in the first direction D1 is, thereby to form a space between the bonding pads 2021 and the driver chip 201 to accommodate the wire group 204, and preventing extra reserving space for setting the wire group 204. Further, a corresponding size difference area may be formed between each bonding pad 2021 and the driver chip 201. In addition, an intersection of multiple size difference areas can be zero. Each size difference area provided with a corresponding wire 2041 can prevent the intersection of the wires 2041 and reduce the difficulty of the layout of the wires 2041, thereby improving the reliability of the work of the wire group 204. Certainly, as shown in FIG. 8, the bonding pads 2021 can also be placed horizontally and arranged in the first direction D1, as long as the projection of the bonding pad group 202 composed of the bonding pads 2021 on the first auxiliary line L1 overlaps the projection of the driver chip 201 on the first auxiliary line L1.

In one embodiment, as shown in FIG. 3, an opening 301 is formed in the color filter substrate 30. The driver chip 201 is located in a third area A3 corresponding to the opening 301 on the array substrate 10. It should be noted that in order to ensure the accuracy of the alignment of the color filter substrate 30 and the array substrate 10, the color filter substrate 30 can be set relative to the array substrate 10 and fixed on the array substrate 10. Then, make the color filter substrate 30 cover the bonding pad group 202 according to the distribution of the bonding pad group 202. The color filter substrate 30 is cut to expose the third area A3 in the second area A2 where the bonding pad group 202 is not provided to facilitate the later setting of the driver chip 201. Specifically, the driver chip 201 can be fixed and electrically connected to the array substrate 10 by bonding in the third area A3. Specifically, a plurality of pins of the driver chip 201 can be electrically connected to a plurality of pins in the third area A3 of the array substrate 10 through an anisotropic conductive adhesive, and can be further electrically connected to the driving wiring 90 located in the second area A2.

It can be understood that the driver chip 201 is generally fixed to the array substrate 10 after the assembly of the array substrate 10 and the color filter substrate 30 is completed. Therefore, in this embodiment, the opening 301 is provided to expose the third area A3 on the array substrate 10 to facilitate disposition of the driver chip 201 in the third area A3. It should be noted that, as noted above, since the wire group 204 extends from the third area A3 to connect to the bonding pad group 202, the wire group 204 can be formed before the color film substrate 30 is assembled, so that incapability of formation of the wire group 204 beyond the third area A3 can be prevented after the color filter substrate 30 is assembled.

In one embodiment, as shown in FIG. 3 and FIG. 9, the display panel 100 further includes a sealant 40 located between the color filter substrate 30 and the array substrate 10 and disposed at least opposite to a periphery of the opening 301. It should be noted that the periphery of the opening 301 makes electrical components and wires in the second area A2 contact the outside air and water vapor. In this embodiment, by providing the sealant 40 at least opposite to the periphery of the opening 301, it is possible to prevent outside air and moisture from entering the second area A2 exclusive of the third area A3. In addition, the sealant 40 can also be arranged opposite to a periphery of the array substrate 10, which also prevents outside air and moisture from entering the second area A2 exclusive of the third area A3.

Specifically, for example, a material of the sealant 40 may be an insulating material. For example, as shown in FIG. 9, the sealant 40 can be arranged to bypass the bonding pad group 202, which can prevent blocking a path of electrical connection between the bonding pad group 202 and the flexible printed circuit board 203. As another example, a material of the sealant 40 may be a conductive material, and the sealant 40 may be arranged in contact with the bonding pad 2021 to facilitate formation of the path of electrical connection between the bonding pad group 202 and the flexible printed circuit board 203. It should be noted that the disposition of the sealant 40 should prevent connecting any bonding pads 2021 to prevent short-circuiting of the two bonding pads 2021.

In one embodiment, as shown in FIG. 3 and FIG. 9, the display panel 100 further includes a plurality of supporting parts 50 located between the color filter substrate 30 and the array substrate 10, and the plurality of supporting parts 50 are arranged at least along the periphery of the opening 301. It can be understood that since a path along the periphery of the opening 301 is longer, and considering the stability of cell-assembly of the array substrate 10 and the color filter substrate 30, the supporting parts 50 in this embodiment are located at least along the periphery of the opening 301, which can ensure the fixing effect on the periphery of the opening 301 and improve the stability of cell-assembly of the array substrate 10 and the color filter substrate 30. Further, the supporting parts 50 may be evenly distributed in the area of the second area A2 excluding the third area A3 to further support the array substrate 10 and the color filter substrate 30. Specifically, the sealant 40 and the supporting parts 50 may be formed before the cell-assembly of the array substrate 10 and the color filter substrate 30.

In one embodiment, as shown in FIGS. 2 and 4, the driver chip 201 is located on the side of the array substrate 10 away from the color filter substrate 30; specifically, as shown in FIGS. 2, 4, 10, and 11, the driver chip 201 is fixed on the side of the flexible printed circuit board 203 away from the color filter substrate 30, the driver chip 201 is electrically connected to the flexible printed circuit board 203, and the bonding pad group 202 is electrically connected to the driving wires 90.

As described above, the driver chip 201 is electrically connected to the flexible printed circuit board 203, the flexible printed circuit board 203 is electrically connected to the bonding pad group 202, and the bonding pad group 202 is electrically connected to the driving wires 90. That is, Specifically, the number of flexible printed circuit boards 203 may be two, for example, as shown in FIGS. 2 and 4, the number of the driver chip 201 may be one, and the driver chip 201 may be arranged close to a middle of the second area A2 so as to be fixed and electrically connected to the two flexible printed circuit boards 203 located on both sides of the second area A2. As another example, as shown in FIG. 10 and FIG. 11, the number of driver chips 201 can be two, and the two driver chips 201 and the two flexible printed circuit boards 203 are in a one-to-one correspondence with each other. Each driver chip 201 can be arranged close to the corresponding flexible printed circuit board 203 so as to be fixed and electrically connected to the corresponding flexible printed circuit board 203.

It can be understood that the flexible printed circuit board 203 and the driver chip 201 in this embodiment can be considered to be packaged by a chip on film (COF) technology. The driver chip 201 is fixed on the flexible printed circuit board 203. The flexible printed circuit board 203 is bent from the side of the array substrate 10 close to the bonding pad group 202 to the side of the array substrate 10 away from the color filter substrate 30, so that the driver chip 201 is fixed to the flexible printed circuit board 203 away from the color film substrate 30. Specifically, the driver chip 201 is loaded with an original signal. Further, a driving signal generated by processing the original signal through the driver chip 201 is transmitted to a light-emitting device through the flexible printed circuit board 203, the bonding pad group 202, and the driving wirings 90 in sequence so as to control image displaying of the display panel 100.

In one embodiment, as shown in FIGS. 1, 2, and 7 to 10, at least one bonding pad group 202 includes a plurality of the bonding pads 2021 arranged in the second direction D2 or the first direction D1. Specifically, for COG technology packaging, for example, as shown in FIGS. 1, 3, 7, and 9, the bonding pads 2021 may be arranged in the second direction D2. Correspondingly, as shown in FIGS. 3 and 7, the flexible printed circuit board can be connected to the outer side of the second area A2 parallel to the second direction D2 to be electrically connected to the end of each bonding pad 2021 away from the first area A1; Another example is shown in FIG. 8, the bonding pads 2021 may be arranged in the first direction D1.

Correspondingly, the flexible printed circuit board can be connected to the outside of the second area A2 parallel to the first direction D1 to be electrically connected to the end of each bonding pad 2021 close to the second area A2. Specifically, for COG technology packaging, for example, as shown in FIGS. 2, 4, and 10, the bonding pads 2021 may be arranged in the first direction D1. Correspondingly, as shown in FIGS. 4 and 10, the flexible printed circuit board can be connected to the outer side of the second area A2 parallel to the first direction D1 to be electrically connected to the end of each bonding pad 2021 close to the second area A2.

In one embodiment, as shown in FIGS. 2, 4, 8 and 10, each of the bonding pad groups 202 includes a plurality of the bonding pads 2021 arranged in the first direction D1, and each of the bonding pads 2021 includes a contact end close to the edge of the display panel. Specifically, as shown in FIGS. 4, 8, and 10, the flexible printed circuit board 203 is arranged close to the contact ends in the bonding pad group 202, and the flexible printed circuit board 203 is connected to the contact ends. It can be understood that, as noted above, for COG or COF technology packaging, the bonding pads 2021 are arranged in the first direction D1 relative to the second direction D2. Since the flexible printed circuit board 203 is not disposed on a side of the second area A2 away from the first area A1, the size of the display panel 100 in the first direction D1 can be further reduced, which is conducive to the development of the narrow bezel of the display panel.

In one embodiment, as shown in FIGS. 2, 4, 8, and 10, the first area A1 includes a fourth area A4 adjoining a periphery of the array substrate 10 in the first direction D1; specifically, the driving wirings 90 located in the fourth area A4 are arranged in layers, and the driving wirings 90 located in different layers are electrically connected through via holes.

It should be noted that, on the basis that the bonding pad group 202 includes the bonding pads 2021 arranged in the first direction D1, that is, the flexible printed circuit board 203 is connected to the side of the array substrate 10 parallel to the first direction D1, the size of the array substrate 10 in the second direction D2 will be additionally used for the above-mentioned arrangement. It can be understood that, in this embodiment, the driving wirings 90 in the fourth area A4 are disposed in a stacked arrangement, and the driving wirings 90 located in different layers are electrically connected through the via holes. That is, the driving wirings 90 originally located in the same layer are stacked and the signal transmission is maintained through the via holes, thereby preventing too much space of the array substrate in the second direction D2 from being occupied due to the arrangement of the driving wirings 90 in the same layer, which effectively shortens the size of the array substrate 10 in the second direction D2, thereby preventing the increase in borders on the left and right edges of the display panel while achieving the narrow bezel at the lower edge of the display panel. Certainly, in this embodiment, the driving wirings 90 located in a fifth area of the array substrate 10 opposite to the fourth area A4 can also be arranged in layers, and the driving wirings 90 located in different layers can also be electrically connected through via holes.

In one embodiment, as shown in FIGS. 5, 6, 10, 11, and 12, the driving assembly 20 further includes a conductive part 209 located between a side of the display panel 100 and the flexible printed circuit board 203; one side of the conductive part 209 is electrically connected to the bonding pad group 202, and the other side of the conductive part 209 is electrically connected to the flexible printed circuit board 203. It can be understood from the above disclosure, the flexible printed circuit board 203 is connected to the side of the display panel 100 close to the bonding pad group 202. In this embodiment, by providing the conductive portion 209 between the side of the display panel 100 and the flexible printed circuit board 203, the electrical connection between the flexible printed circuit board 203 and the bonding pad group 202 can be realized, wherein the flexible printed circuit board 203 can be bonded to the conductive portion 209 by anisotropic conductive adhesive. Therefore, in this embodiment, by providing the conductive portion 209, the flexible printed circuit board 203 arranged from the side of the array substrate 10 close to the color filter substrate 30 and bent downward to form a bending part can be prevented, so that the size of the display panel 100 in the first direction D1 can be shortened.

Specifically, a number of conductive portions 209 may be equal to a number of bonding pads 2021 in the corresponding bonding pad group 202, and a plurality of the conductive portions 209 and the bonding pads 2021 are in a one-to-one correspondence with each other. Each conductive portion 209 is located close to and electrically connected to the corresponding bonding pad 2021, so that the corresponding bonding pad 2021 is electrically connected to the flexible printed circuit board 203. Specifically, as shown in FIGS. 3, 5, and 12, for example, when the number of the bonding pads 2021 in the bonding pad group 202 is four, at four end portions of the four bonding pads 2021 close to the edge of the array substrate 10, four conductive portions 209 can be provided in a one-to-one correspondence with the four bonding pads 2021. As shown in FIGS. 4, 6, and 10, for example, when the number of the bonding pads 2021 in the bonding pad group 202 is three, at end portions of the three bonding pads 2021 close to the edge of the array substrate 10, three conductive portions 209 can be provided in a one-to-one correspondence with the three bonding pads 2021. It should be noted that, as shown in FIG. 12, after the cell-assembly of the array substrate 10 and the color filter substrate 30, all the conductive portions 209 may be formed on the side of the display panel 100 corresponding to the bonding pads 2021 first, then, a flexible short-circuit portion 203 is formed on a side of the conductive portion 209 away from the side of the display panel 100.

In one embodiment, as shown in FIGS. 5, 6, and 11, the display panel 100 further includes a fixing portion 60 located on the edge of the display panel 100 close to the flexible printed circuit board 203, and connected between the edge of the display panel 100 and the flexible printed circuit board 203. It should be noted that the conductive portion 209 is configured to electrically connect the bonding pad group 202 and the flexible printed circuit board 203, and is not sufficient to fix the flexible printed circuit board 203 to the side of the display panel 100. It can be understood that the flexible printed circuit board 203 can be fixed to the side of the display panel 100 by providing the fixing portion 60 in this embodiment, thereby improving the stability of the display panel 100. Specifically, a size of the fixing portion 60 in an arrangement direction of the corresponding bonding pads 2021 may be greater than or equal to a size occupied by the bonding pads 2021. Further, the fixing portion 60 may be connected between the edge of the array substrate 10 and the flexible printed circuit board 203, and connected between an edge of the color filter substrate 30 and the flexible printed circuit board 203. In addition, the fixing portion 60 can also cover top and bottom ends of the conductive portion 209 to further improve the stability of the conductive portion 209 and the flexible printed circuit board 203 fixed to the side of the display panel 100.

It should be noted that, as shown in FIG. 13, after the cell-assembly of the array substrate 10 and the color filter substrate 30, all the conductive portions 209 and the flexible printed circuit board 203 may be disposed on the side of the display panel 100 corresponding to the bonding pads 2021. Then, a dispensing process is performed to form all the fixed portions 60 between the edge of the array substrate 10 and the flexible printed circuit board 203 and between the edge of the color filter substrate 30 and the flexible printed circuit board 203. Further, as shown in FIG. 13 and FIG. 6, the flexible printed circuit board 203 is bent to the side of the array substrate 10 away from the color filter substrate 30 to fix the flexible printed circuit board 203 on the side of the array substrate 10 away from the color filter substrate 30. As shown in FIG. 13, in a thickness direction of the display panel, an upper surface of the fixing portion 60 close to the color filter substrate 30 may not exceed an upper surface of the upper polarizer on the side of the color filter substrate 30 away from the array substrate 10; likewise, a lower surface of the fixing portion 60 close to the array substrate 10 may not exceed a lower surface of the lower polarizer on the side of the color filter substrate 30 away from the array substrate 10 to prevent interference.

The present invention provides the display panel including: the array substrate including the first area and the second area arranged in the first direction, and the first area is configured for display. The driving assembly includes the driver chip located in the second area and at least one bonding pad group electrically connected to the driver chip. The driving assembly is electrically connected to the driving wirings located in the first area. The color filter substrate and the array substrate are arranged oppositely, and the color filter substrate is formed with the opening. The driver chip is located in the third area opposite to the opening on the side of the array substrate close to the color filter substrate. Specifically, an orthographic projection of the driver chip on a first plane overlaps an orthographic projection of the bonding pad group on the first plane, and the first plane is parallel to the first direction and perpendicular to the display panel. In the present invention, the driver chip is disposed such that the driver chip after extending in the second direction can overlap the bonding pad group, making the projection of the driver chip in the second direction overlap the projection of the bonding pad group in the second direction. The second direction is perpendicular to the first direction. In this fashion, the projections of the bonding pad group and the driver chip can be prevented from separately occupying extra space in the first direction. In addition, a relatively large size of a sum of the projections in the first direction can be prevented, which effectively shortens the size of the array substrate in the first direction, and is beneficial to the development of the narrow bezel of the display panel.

The above describes the embodiments of the present invention in detail. The descriptions of the above embodiments are only used to help understand the technical solutions and kernel ideas of the present invention; those of ordinary skill in the art should understand that they can still modify the technical solutions described in the foregoing embodiments, whereas these modifications or substitutions do not deviate the essence of the corresponding technical solutions from the scope of the technical solutions of the embodiments of the present invention.

What is claimed is:

1. A display panel, comprising:
an array substrate comprising a first area and a second area arranged in a first direction;
a driving assembly comprising a driver chip located in the second area and at least a bonding pad group electrically connected to the driver chip, and the driving assembly electrically connected to driving wirings located in the first area; and
a color filter substrate disposed opposite to the array substrate, wherein an opening is located at the color filter substrate, and the driver chip is located in a third area opposite to the opening on a side of the array substrate close to the color filter substrate;
wherein an orthographic projection of the driver chip on a first plane overlaps an orthographic projection of the bonding pad group on the first plane, and the first plane is parallel to the first direction and perpendicular to the display panel;
wherein the bonding pad group is disposed on both sides of the driver chip, the orthographic projection of the driver chip on the first plane is within the orthographic projection of the bonding pad group on the first plane, or the orthographic projection of the bonding pad group on the first plane is within the orthographic projection of the driver chip on the first plane

2. The display panel of claim 1, wherein the bonding pad group is located on the side of the array substrate close to the color filter substrate;
wherein the driving assembly further comprises a flexible printed circuit board connected to a side of the display panel close to the bonding pad group and bent such that the flexible printed circuit board is fixed to a side of the array substrate away from the color filter substrate, and the flexible printed circuit board is electrically connected to the bonding pad group.

3. The display panel of claim 2, wherein the bonding pad group is electrically connected to the driver chip through a wire group, and the driver chip is electrically connected to the driving wirings.

4. The display panel of claim 3, wherein the orthographic projection of the driver chip on the first plane is within the orthographic projection of the bonding pad group on the first plane;
wherein the bonding pad group comprises a plurality of bonding pads, and each of the bonding pads comprises a first end and a second end that are arranged opposite to each other in the first direction, wherein a plurality of the first ends in the bonding pad group are arranged in alignment with each other in a second direction, and the second direction is perpendicular to the first direction, wherein a size of one of adjacent ones of the bonding pads close to the driver chip in the first direction is less than a size of the other one of the adjacent bonding pads away from the driver chip in the first direction, so that the second ends in the bonding pad group each have a size difference in the first direction; and
wherein the wire group comprises a plurality of wires arranged in a one-to-one correspondence with the bonding pads, the second end of each of the bonding pads is electrically connected to the driver chip through a corresponding one of the wires, and each of the wires is located in a size difference area defined by the corresponding bonding pad.

5. The display panel of claim 3, further comprising:
a sealant located between the color filter substrate and the array substrate and disposed at least opposite to a periphery of the opening.

6. The display panel of claim 3, further comprising:
a plurality of supporting parts located between the color filter substrate and the array substrate, and the supporting parts are arranged at least along a periphery of the opening.

7. The display panel of claim 2, wherein at least one of the bonding pad groups comprises a plurality of the bonding pads arranged in the second direction or in the first direction, wherein the second direction is perpendicular to the first direction.

8. A display panel, comprising:
an array substrate comprising a first area and a second area arranged in a first direction;
a driving assembly comprising a driver chip located in the second area and at least a bonding pad group electrically connected to the driver chip, and the driving assembly electrically connected to driving wirings located in the first area;
a color filter substrate disposed opposite to the array substrate, wherein an opening is located at the color filter substrate, and the driver chip is located in a third area opposite to the opening on a side of the array substrate close to the color filter substrate;
wherein an orthographic projection of the driver chip on a first plane overlaps an orthographic projection of the bonding pad group on the first plane, and the first plane is parallel to the first direction and perpendicular to the display panel.

9. The display panel of claim 8, wherein the bonding pad group is located on the side of the array substrate close to the color filter substrate;
wherein the driving assembly further comprises a flexible printed circuit board connected to a side of the display panel close to the bonding pad group and bent such that the flexible printed circuit board is fixed to a side of the array substrate away from the color filter substrate, and the flexible printed circuit board is electrically connected to the bonding pad group.

10. The display panel of claim 9, wherein the bonding pad group is electrically connected to the driver chip through a wire group, and the driver chip is electrically connected to the driving wirings.

11. The display panel of claim 10, wherein the bonding pad group is disposed on both sides of the driver chip.

12. The display panel of claim 10, wherein the orthographic projection of the driver chip on the first plane is within the orthographic projection of the bonding pad group on the first plane, or the orthographic projection of the bonding pad group on the first plane is within the orthographic projection of the driver chip on the first plane.

13. The display panel of claim 10, wherein the orthographic projection of the driver chip on the first plane is within the orthographic projection of the bonding pad group on the first plane;
wherein the bonding pad group comprises a plurality of bonding pads, and each of the bonding pads comprises a first end and a second end that are arranged opposite to each other in the first direction, wherein a plurality of the first ends in the bonding pad group are arranged in alignment with each other in a second direction, and the second direction is perpendicular to the first direction, wherein a size of one of adjacent ones of the bonding pads close to the driver chip in the first direction is less than a size of the other one of the adjacent bonding pads away from the driver chip in the first direction, so that the second ends in the bonding pad group each have a size difference in the first direction; and
wherein the wire group comprises a plurality of wires arranged in a one-to-one correspondence with the bonding pads, the second end of each of the bonding pads is electrically connected to the driver chip through a corresponding one of the wires, and each of the wires is located in a size difference area defined by the corresponding bonding pad.

14. The display panel of claim 10, further comprising:
a sealant located between the color filter substrate and the array substrate and disposed at least opposite to a periphery of the opening.

15. The display panel of claim 10, further comprising:
a plurality of supporting parts located between the color filter substrate and the array substrate, and the supporting parts are arranged at least along a periphery of the opening.

16. The display panel of claim 9, wherein at least one of the bonding pad groups comprises a plurality of the bonding pads arranged in the second direction or in the first direction, wherein the second direction is perpendicular to the first direction.

17. The display panel of claim 16, wherein each of the bonding pad groups comprises a plurality of the bonding pads arranged in the first direction, and each of the bonding pads comprises a contact end disposed close to an edge of the display panel;
wherein the flexible printed circuit board is arranged close to and connected to the plurality contact ends in the bonding pad group.

18. The display panel of claim 17, wherein the first area comprises a fourth area adjoining a periphery of the array substrate in the first direction;
wherein the driving wirings located in the fourth area are arranged in layers, and the driving wirings located in different layers are electrically connected through via holes.

19. The display panel of claim 9, wherein the driving assembly further comprises a conductive portion located between a side of the display panel and the flexible printed circuit board;
wherein one side of the conductive portion is electrically connected to the bonding pad group, and the other side is electrically connected to the flexible printed circuit board.

20. The display panel of claim 9, further comprising:
a fixing part located on an edge of the display panel close to the flexible printed circuit board and connected to the edge of the display panel and the flexible printed circuit board.
